(19) United States
(12) Patent Application Publication
(10) Pub. No.: US 2007/0246799 A1
(43) Pub. Date: Oct. 25, 2007

(54) SEMICONDUCTOR DEVICE

(75) Inventor: Yuichi KAWANO, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Chiyoda-ku (JP)

(21) Appl. No.: 11/733,975

(22) Filed: Apr. 11, 2007

(30) Foreign Application Priority Data
Apr. 21, 2006 (JP) 2006-117720

(51) Int. Cl. H01L 29/00

(52) U.S. Cl. 257/532

(57) ABSTRACT

A first opening portion for via hole opening is formed above an electrode groove and a second opening portion for via hole opening for connecting with wiring layer is formed on interlayer insulation film at a position corresponding to the top portion of wiring layer provided out of a capacitor formation area. At this time, the diameter of the opening of the first opening portion is set larger than the second opening portion. If the diameter of the second opening portion is 0.36 μm, the diameter of the opening of the first opening portion is set to 0.38 μm.

### BACKGROUND OF THE INVENTION

1. Field of the Invention

The present invention relates to a semiconductor device and more particularly to a semiconductor device having a metal insulator metal (MIM) structured capacitor.

2. Description of the Background Art

In a communication LSI and high-speed CMOS logic device, reduction of dielectric in an interlayer insulation film and use of Cu wiring based on Damascene method have been generally used in order to achieve a high-speed operation. Further, in a communication LSI and high-speed CMOS logic device, generally its analog circuit possesses a MIM structure capacitor.

According to the Damascene method, a groove for wiring and/or a hole for contact plug is formed in the interlayer insulation film and after copper is applied therein, an excessive part of the copper is removed by chemical mechanical polishing (CMP). Single Damascene of forming the wire or contact plug individually and dual Damascene of forming the wire and contact hole at the same time are available.

The CMP is indispensable even if either method is adopted and when wiring having a larger area than the contact plug is formed, such phenomenon as dishing or erosion occurs upon polishing.

The dishing refers to such a phenomenon that a polishing pad for use in the CMP is deformed so that the sectional shape of the wire is dented in a dish-like form and the erosion refers to such a phenomenon that not only the surface of the wire but also the surface of the interlayer insulation film is polished at the same time in a portion in which the wires are located densely.

For example, Japanese Patent Application Laid-Open No. 2004-14828 has disclosed that occurrence of the dishing and erosion is prevented by selecting the polishing condition of the CMP appropriately.

In recent years, technology of forming the MIM structure capacitor using the Damascene process has been developed. Although the dishing and erosion are more serious because the electrode of the capacitor has a larger area than the wire, the above-mentioned Japanese Patent Application Laid-Open No. 2004-14828 does not include any description about the MIM structure capacitor.

### SUMMARY OF THE INVENTION

The present invention provides a semiconductor device which prevents a capacitor therein from failing due to dishing or erosion when the capacitor having a MIM structure is formed using Damascene process.

The semiconductor device of the present invention includes a capacitor having: an interlayer insulation film provided above a semiconductor substrate; a lower electrode provided in the top layer portion of the interlayer insulation film; a dielectric film provided on the lower electrode; and an upper electrode provided so as to face toward the lower electrode across the dielectric film. The lower electrode is integrated with a contact plug provided so as to penetrate the interlayer insulation film from the bottom portion in a direction perpendicular to a main surface of the semiconductor substrate, and a diameter of the contact plug is set larger than a diameter of another contact plug provided so as to penetrate the interlayer insulation film in the direction perpendicular to the main surface of the semiconductor substrate.

As described above, because the diameter of the contact plug provided such that it penetrates the interlayer insulation film in the direction perpendicular to the main surface of the semiconductor substrate from the bottom portion of the lower electrode is set larger than the diameter of the other contact plugs, the focus margin of lithography at the time of manufacturing the lower electrode is increased, so that no failure occurs in formation of the contact plugs even if the electrode groove for formation of the lower electrode is formed deeper than usually. As a consequence, the thickness of the lower electrode specified by the depth of the electrode groove is increased, so that it is sufficiently large compared with the excessive polishing amount by dishing or erosion, even if the surface of the lower electrode is dented in a dish-like form due to the dishing or erosion by excessive polishing by the CMP. As a result, the lower electrode is never removed completely even in a local area, thereby preventing the capacitor from failing.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor device having a MIM structure capacitor not of the present invention;

FIG. 2 is a diagram showing a lower electrode model for explaining over-polishing of the lower electrode;

FIGS. 3-9 are sectional views showing manufacturing process of a first embodiment of the semiconductor device of the present invention;

FIG. 10 is a diagram showing relation between focus offset and via hole diameter;

FIGS. 11 and 12 are sectional views for explaining relation between the quantity of via holes in an electrode groove and over-polishing of the lower electrode; and

FIG. 13 is a plan view for explaining a structure of a second embodiment of the semiconductor device of the present invention.

### DESCRIPTION OF THE PREFERRED EMBODIMENTS

### Introduction

Prior to description of the embodiments of the present invention, dishing which occurs in a MIM structure capacitor will be explained.

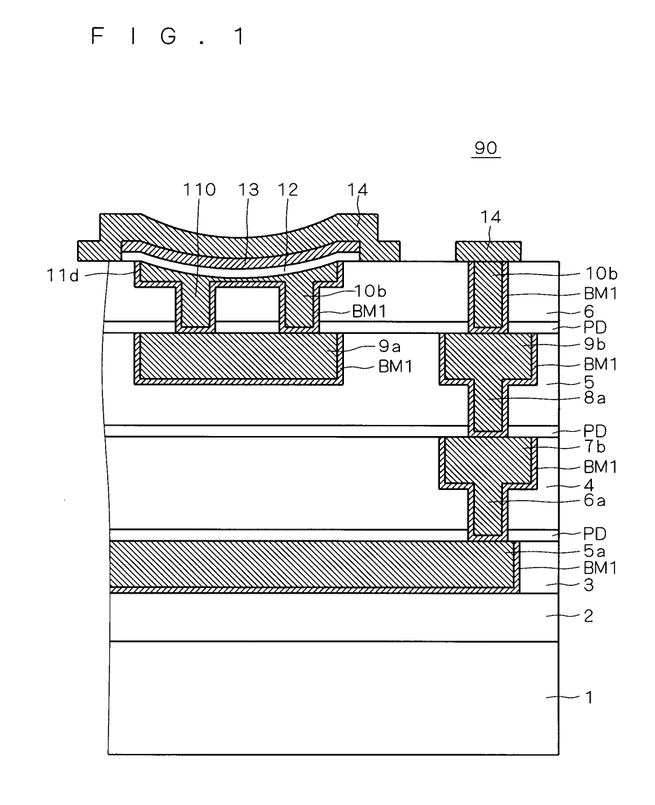

FIG. 1 is a sectional view showing a semiconductor device 90 having the MIM structure capacitor not of the present invention.

As shown in FIG. 1, an interlayer insulation film 2 composed of silicon oxide film (SiO₂) formed according to, for example, CVD method is provided on a semiconductor substrate 1 such as silicon substrate.

Although FIG. 1 shows an example that no semiconductor device is formed on the semiconductor substrate 1, the semiconductor device such as MOS transistor is formed on other portion on the same semiconductor substrate 1 and interlayer insulation film 2 for covering the semiconductor device is provided.

An interlayer insulation film 3 composed of SiOC or the like formed according to the CVD method is provided on the interlayer insulation film 2 and a copper wiring layer 5a is provided on the surface of the interlayer insulation film 3. The interlayer insulation film 3 is not restricted to SiOC but any film called low-k film such as SiC film may be used. Of course, a film having a relatively high dielectric constant such as silicon oxide film may be used.

The wiring layer 5a is formed according to Damascene method and the wiring layer 5a is surrounded by a barrier metal film BM1.

The barrier metal film BM1 is constituted of multilayer film in which tantalum nitride (TaN), tantalum (Ta), titan (Ti), and titan nitride (TiN) are overlaid in this order, or multilayer film in which tantalum (Ta) and tantalum nitride (TaN) are overlaid in this order or multilayer film in which titan (Ti) and titan nitride (TiN) are overlaid in this order.

An insulation film such as SiN film is formed on the interlayer insulation film 3 and a dispersion preventing insulation film PD for preventing dispersion of Cu is provided. In the meantime, the dispersion preventing insulation film PD functions as protective film (cap insulation film) for protecting the interlayer insulation film of SiOC having a low mechanical strength and sometimes silicon oxide film may be used.

An interlayer insulation film 4 constituted of SiOC is provided on the dispersion preventing insulation film PD and a copper wiring layer 7b is provided in the top layer of the interlayer insulation film 4. A contact plug 6a which goes through the interlayer insulation film 4 and the dispersion preventing insulation film PD to connect the wiring layer 7b and the wiring layer 5a electrically is provided in the lower layer portion of the interlayer insulation film 4. In the meantime, the wiring layer 7b and the plug 6a are formed by dual Damascene so that they are integrated. Both of them are surrounded by the barrier metal BM1. The diameter of the contact plug 6a is set to 0.36 μm.

A dispersion preventing insulation film PD is provided on the interlayer insulation film 4 and the interlayer insulation film 5 composed of SiOC or the like is provided on the dispersion preventing insulation film PD. Then, a plurality of copper wiring layers 9a and 9b are provided in the top layer portion of the interlayer insulation film 5 and the wiring layer 9b is constructed to be connected to the wiring layer 7b by a contact plug 8a which goes through the interlayer insulation film 5 and the dispersion preventing insulation film PD and reaches the wiring layer 7b. In the meantime, the wiring layer 9b and a contact plug 8a are formed according to the dual Damascene so that they are integrated with each other. The wiring layers 9a, 9b and the contact plug 8a are surrounded by the barrier metal film BM1. In the meantime, the diameter of the contact plug 8a is set to 0.36 μm.

The dispersion preventing insulation film PD is provided on the interlayer insulation film 5 and the interlayer insulation film 6 composed of silicon oxide film or the like is provided on the dispersion preventing insulation film PD.

A lower electrode 110 (setting depth; about 250 nm) of the capacitor constituted of tungsten (W) formed according to the CVC method is provided in the top layer portion of the interlayer insulation film 6 and the lower electrode 110 is connected electrically to the wiring layer 9a by a plurality of contact plugs 10b which go through the interlayer insulation film 6 and the dispersion preventing insulation film PD and reach the wiring layer 9a. In the meantime, the diameter of the contact plug 10b is set to 0.36 μm.

Here, the lower electrode 110 and the contact plug 10b are formed according to the dual Damascene so that they are integrated.

The contact plug 10b which go through the interlayer insulation film 6 and the dispersion preventing insulation film PD and reach the wiring layer 9b is provided and a topmost layer wiring 14 is provided on the contact plug 10b. In the meantime, the lower electrode 110 and the contact plug 10b are surrounded by the barrier metal BM1.

As shown in FIG. 1, the surface of the lower electrode 110 is dented in a dish-like form by dishing and few electrodes are left in the central portion.

A capacitor dielectric film 12 composed of for example silicon nitride film is provided for covering the lower electrode 110 and the capacitor dielectric film 12 is also dented in correspondence to the dent of the lower electrode 110.

An upper electrode 13 of the capacitor composed of for example, TiN film is provided on the capacitor dielectric film 12 and topmost layer wiring 14 constituted of for example aluminum film (or Cu film) is provided in order to cover the upper electrode 13 and the capacitor dielectric film 12. Further, the topmost layer wiring 14 is selectively provided on the contact plug 10b also.

When the lower electrode 110 is scraped by dishing or erosion, the interlayer insulation film 6 is exposed or nearly exposed. In this case, the capacitor dielectric film 12 which is supposed to form an interface with the tungsten film can form an interface with the interlayer insulation film 6 and if the interface condition is changed, the capacitor can be subjected to pressure resistance failure.

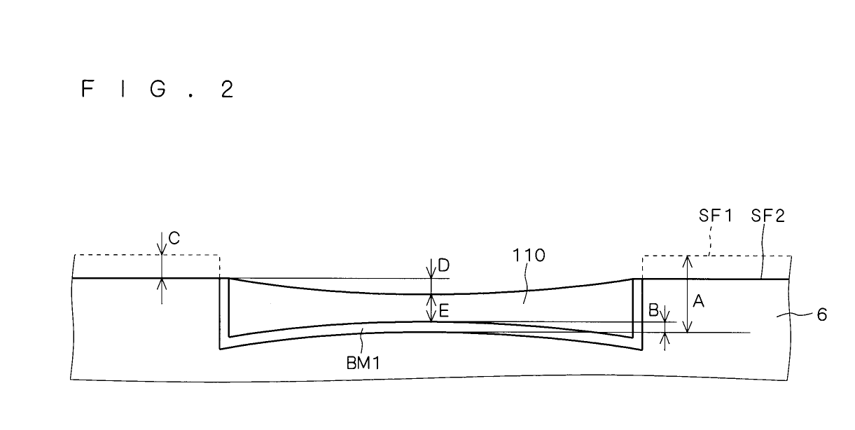

To what extent the lower electrode 110 is scraped by dishing or erosion will be described using a model shown in FIG. 2.

FIG. 2 is a diagram showing the sectional shape after the lower electrode 110 is formed and only the lower electrode 110 is indicated for convenience.

In FIG. 2, the position of a main face SF1 of the interlayer insulation film 6 at a stage in which an electrode groove for forming the lower electrode 110 in the interlayer insulation film 6 before the lower electrode 110 is polished by the CMP is indicated with a dotted line. The depth of the electrode groove, that is, the length from the main face SF1 up to the bottom face of the central portion of the electrode groove is assumed to be electrode depth A.

The thickness of the barrier metal film BM1 is assumed to be B and the thickness of the interlayer insulation film 6 removed together with tungsten by the CMP is assumed to be interlayer insulation film cutting thickness C.

A difference of step between a main face SF2 of the interlayer insulation film 6 after the CMP and the central portion of the lower electrode 110 is assumed to be dishing amount D and the thickness of the central portion of the lower electrode 110 (excluding the barrier metal film BM1) is assumed to be remaining film amount E.

If the central portion is explained as an example about a case of dishing in which the setting depth of the lower electrode 110 is 250 nm, the lower electrode depth A is 245 nm (measured value), barrier metal thickness B is 88 nm (measured value from a sectional SEM photograph), interlayer insulation film cutting thickness C is 33 nm (obtained by subtracting (B+E) from A) and dishing amount D is 33 nm (obtained by subtracting (B+E) from A) and thus, the remaining film amount E is 124 nm.

The thickness of the central portion of the lower electrode 110 is reduced to about half the setting value by dishing and because a plurality of the capacitors are provided and influence of erosion is present, the thickness of the lower electrode 110 becomes minus, that is, the lower electrode 110 is removed completely.

As described previously, if the lower electrode 110 is removed completely even if locally, the capacitor can be subjected to pressure resistance failure.

Because the inventor et al. have developed a semiconductor device in which removal of the lower electrode by dishing or erosion is prevented, the composition thereof will be described below.

### First Embodiment

The inventor et al. have captured a technical philosophy that the thickness of the lower electrode needs to be increased in order to prevent occurrence of a portion in which the lower electrode is removed completely. However, this technical philosophy has a following problem. That is, the manufacturing method of the lower electrode which the inventor et al. have adopted is a method called trench first of forming the electrode groove for formation of the electrode in the dual Damascene first and in this case, if a deep groove is formed, next the position of a focus position when resist is exposed to light by photolithography so as to form via hole becomes deep. Because there is a limit in the adjustment range of the depth of focus (DOF) of the photolithography unit, if the groove for electrode is deepened, the via hole cannot be formed in a set diameter and consequently, contact with the lower layer wire cannot be secured.

Because the inventor et al have reached a construction effective for solving the above problem, this will be described in the first embodiment of the present invention.

### Manufacturing Method

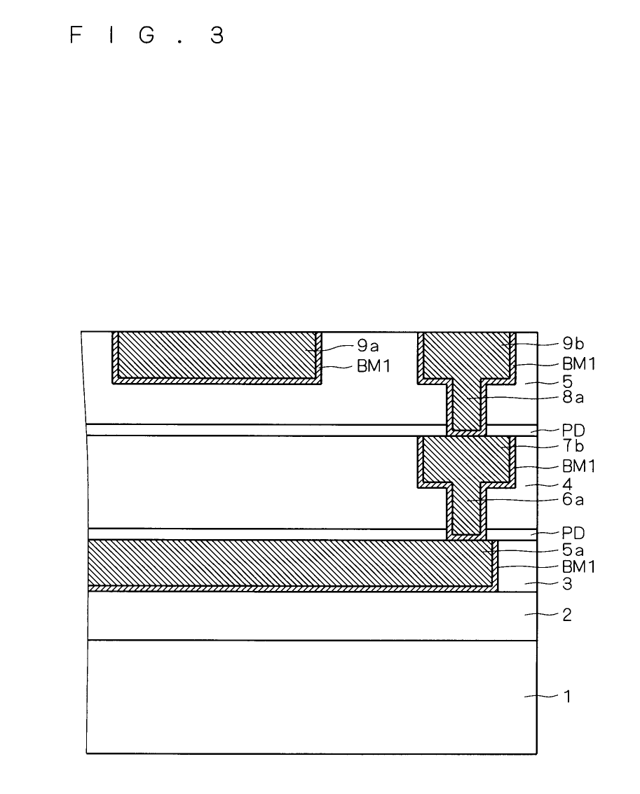

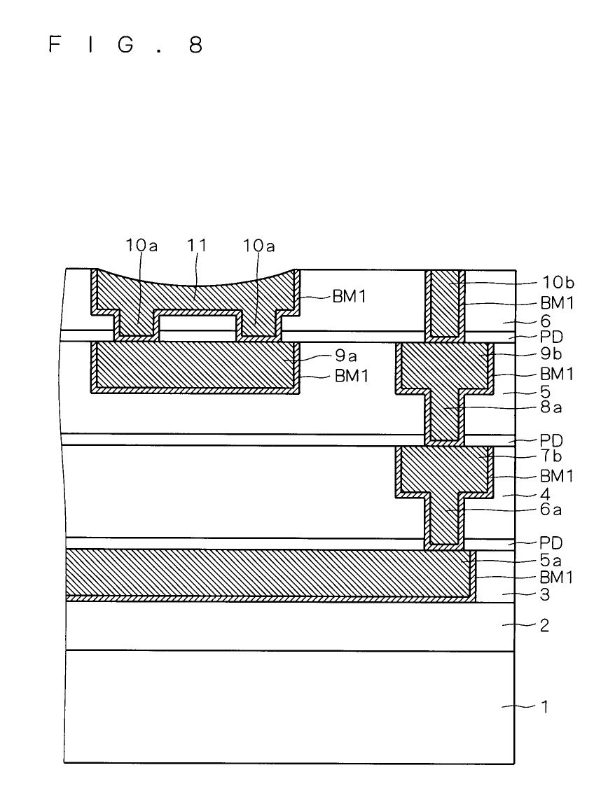

First, the manufacturing method of a semiconductor device 100 according to the present invention will be described with reference to FIGS. 3-9 showing the sectional views in the manufacturing process successively. The structure of the semiconductor device 100 is shown in FIG. 9 indicating a final step. In the meantime, for the semiconductor device 100, like reference numerals are attached to the same components as the semiconductor device 90 shown in FIG. 1 and duplicated description thereof is omitted.

First, a structure having the wiring layers 9a, 9b and contact plug 8a as shown in FIG. 3 is formed using a conventional manufacturing method.

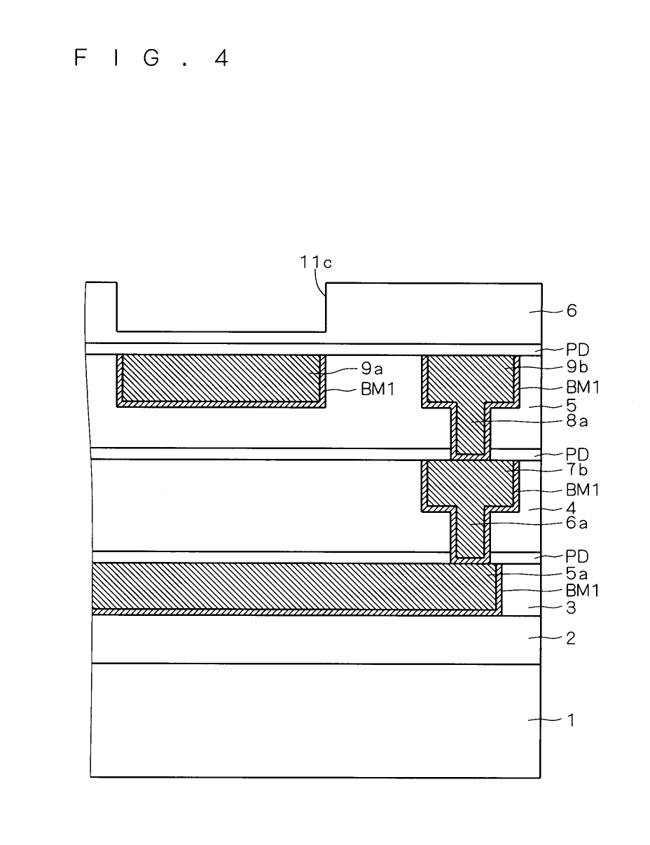

After that, in a step shown in FIG. 4, insulation film such as SiN film is formed on the interlayer insulation film 5 according to the CVD method so as to dispose the dispersion preventing insulation film PD.

After that, the interlayer insulation film 6 of 400-1000 nm in thickness composed of silicon oxide film or the like is formed on the dispersion preventing insulation film PD according to for example the CVD method.

An electrode groove 11c for forming the lower electrode for a capacitor about 350 nm is formed by etching selectively the interlayer insulation film 6 at a position corresponding to the top portion of the wiring layer 9a by photolithography and anistropic etching. This depth is set to a larger value than the electrode groove for forming the lower electrode 110 of the semiconductor device 90 shown in FIG. 1.

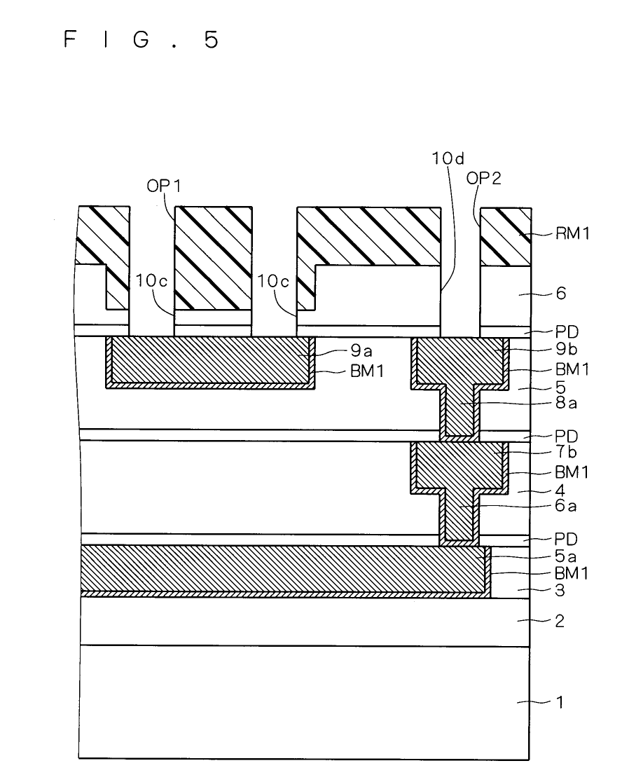

After that, a resist mask RM1 is formed on the interlayer insulation film 6 in a step shown in FIG. 5 and by patterning with photolithography, an opening portion OP1 for via hole opening is formed on the electrode groove 11c and an opening portion OP2 for via hole opening for connecting to the wiring layer 9b is formed on the interlayer insulation film 6 at a position corresponding to the top portion of the wiring layer 9b provided out of a capacitor formation area. At this time, the diameter of an opening of the opening portion OP1 is set larger than the opening OP2 and for example, if the diameter of the opening portion OP2 is 0.36 μm, the opening diameter of the opening portion OP1 is set to 0.38 μm.

Then, anistropic etching is carried out with the resist mask RM1 as an etching mask so as to remove the interlayer insulation film 6 and the dispersion preventing insulation film PD at a portion corresponding to the openings OP1 and OP2. Consequently, via holes 10c and 10d which reach the wiring layers 9a and 9b are formed.

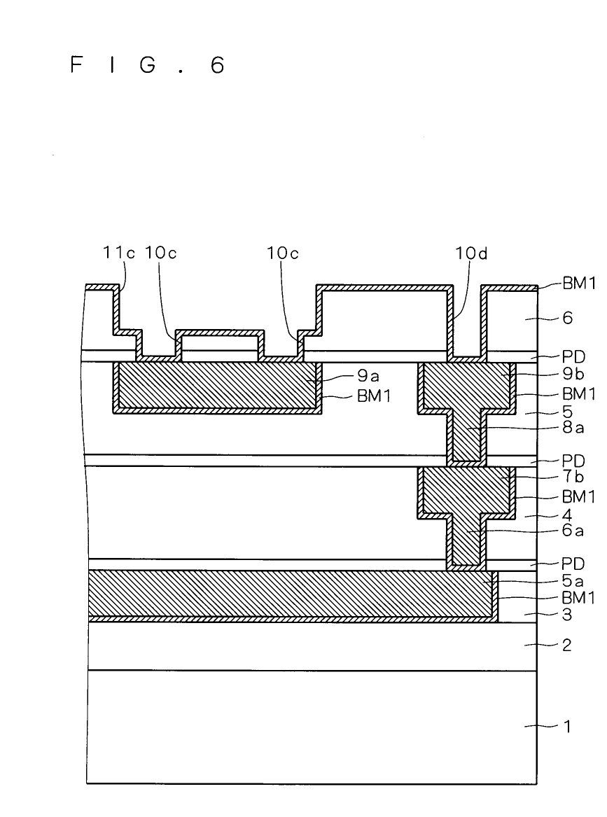

After the resist mask RM1 is removed, the barrier metal film BM1 is formed on an entire surface of the interlayer insulation film 6 by sputtering method in a step shown in FIG. 6. Consequently, an inner face of the electrode groove 11c and inner faces of the via holes 10c and 10d communicatively connecting with the electrode groove 11c are covered with the barrier metal film BM1.

Next, a tungsten film ML1 is formed on an entire surface of the interlayer insulation film 6 covered with the barrier metal film BM1 according to the CVD method in a step shown in FIG. 7 and the electrode groove 11c, the via hole 10c and the via hole 10d are filled with the tungsten film ML1.

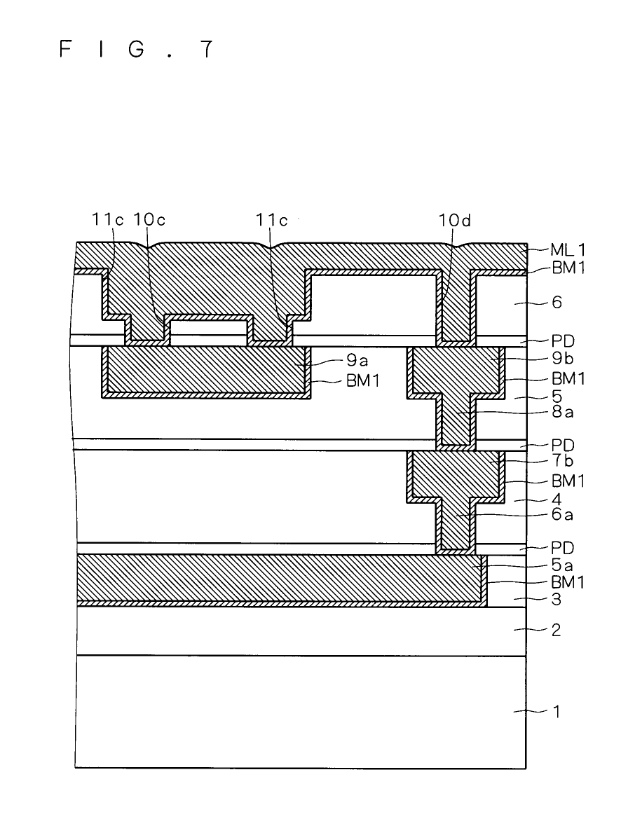

After that, in a step shown in FIG. 8, unnecessary tungsten film ML1 on the interlayer insulation film 6 is polished and removed by the CMP so that the tungsten film ML1 is left in only the electrode groove 11c, and the via holes 10c, 10d so as to form the lower electrode 11 of the capacitor and the contact plugs 10a, 10b.

At this time, dishing or erosion occurs due to excessive polishing by the CMP so that the surface of the lower electrode 11 is dented in a dish-like form. However, because the thickness of the lower electrode 11 (about 350 μm) is sufficiently large as compared with the excessive polishing amount by dishing or erosion, the lower electrode 11 is never removed completely even if locally.

After in a step shown in FIG. 9, the capacitor dielectric film 12 is formed of silicon nitride film according to the CVD method so as to cover the lower electrode 11, the upper electrode 13 is formed of TiN film (or TaN film or W film) according to sputtering method on the capacitor dielectric film 12.

After that, the topmost layer wiring 14 is formed of aluminum film (or Cu film) according to for example, sputtering method so as to cover the top electrode 13 and the capacitor dielectric film 12. The semiconductor device 100 is obtained by patterning the topmost layer wiring 14 on the contact plug 10b also selectively at the same time.

Although the semiconductor device 100 shown in FIG. 9 has five interlayer insulation films, the present invention is not restricted to this example but the present invention can be applied to a semiconductor device composed of more interlayer insulation films or fewer interlayer insulation films.

Although FIG. 9 shows a structure in which the capacitor is formed on the interlayer insulation film 6 on the topmost layer, the capacitor may be provided on any interlayer insulation film other than on the topmost layer.

### Characteristic Operation and Effect

Although as described in FIG. 4, the depth of the electrode groove 11c was set to about 350 nm which is larger than in the semiconductor device 90 shown in FIG. 1, limitation of the adjustment range of the depth of focus (DOF) in the photolithography unit was not problematic.

The reason is that the diameter of the opening portion OP1 was set to 0.38 μm if the diameter of the opening portion OP2 was 0.36 μm.

According to the experiment by the inventor et al, it has been found that if the diameter of the via hole is set large, such a degree in which the diameter of the via hole is changed can be reduced if the depth of focus is changed, that is, the DOF margin (focus margin) can be increased.

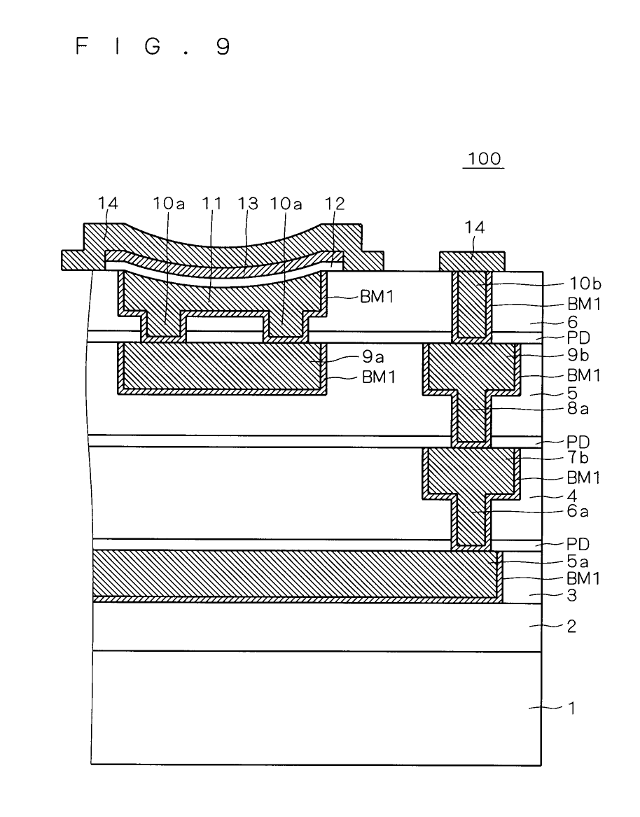

FIG. 10 shows the relation between the focus offset obtained by the inventor et al. and the via hole diameter.

FIG. 10 indicates focus offset (μm) on its abscissa axis and via hole diameter (nm) on its ordinate axis, showing how the via hole diameter changes when the focus offset is changed in case where of forming a via hole of 0.38 μm and a via hole of 0.39 μm. In the meantime, FIG. 10 indicates a direction in which the DOF is deepened as a minus direction.

FIG. 10 shows a focus offset for forming a via hole of 0.38 μm and a via hole of 0.39 μm as an optimum lithography condition with an arrow. Although the range of focus offset in which the diameter of the via hole is not smaller than 0.38 μm when the via hole of 0.38 μm is formed is in a range of from minus 0.7 μm to minus 1.2 μm, the range of focus offset in which the diameter of the via hole is not smaller than 0.39 μm when the via hole of 0.39 μm is formed is in a range of from minus 0.7 μm to minus 1.3 μm, thereby indicating that as the diameter of the via hole is set larger, an influence of a change of the depth of focus is unlikely to be received.

If the diameter of the contact plug 10a to be formed on the bottom portion of the electrode groove 11c is set larger than the diameter of the contact plug 10b to be formed in other portion in the interlayer insulation film 6, the diameter of the contact plug 10b is prevented from being much smaller than its set value even if the setting depth of the electrode groove 11c is set to about 350 nm or deeper by about 100 nm than the semiconductor device 90 shown in FIG. 1.

As described above, while the diameter of the opening portion OP2 is 0.36 μm, the diameter of the opening portion OP1 is 0.38 μm, which corresponds to the diameter of the contact plug 10a and the diameter of the contact plug 10b and as a consequence, the diameter of the contact plug 10a is 1.05 times larger than the diameter of the contact plug 10b.

From FIG. 10, it is evident that the DOF margin can be increased by increasing the diameter. Thus, by setting the diameter of the contact plug which connects the lower electrode of the capacitor with the wiring layer of the lower layer electrically at least 1.05 or more times larger than the diameter of other contact plugs provided in the same interlayer insulation film, the focus margin can be increased securely as compared with other contact plugs in the same interlayer insulation film.

By deepening the electrode groove 11c, the thickness of the lower electrode 11 specified by the depth of the electrode groove 11c is increased. As a consequence, even if dishing or erosion occurs due to excessive polishing by the CMP so that the surface of the lower electrode 11 is dented, the lower electrode 11 is never removed completely even if locally, because the thickness of the lower electrode (about 350 μm) is sufficiently larger than the excessive polishing amount by dishing or erosion.

Findings of the inventor et al. concerning the dishing of the lower electrode will be explained using a diagram showing a sectional shape after the lower electrode is formed of FIG. 2. In the meantime, in a following description, FIG. 2 will be used as a diagram showing a sectional shape after the lower electrode 11 is formed.

Here, the lower electrode depth A is 332 nm (measured value), the barrier metal thickness B is 79 nm (measured value from sectional SEM photograph), interlayer insulation film cutting thickness C is 84 nm (obtained by subtracting (B+E) from A), the dishing amount D is 84 nm (obtained by subtracting (B+E) from A) and the remaining film amount E is 169 nm.

Although the thickness of the central portion of the lower electrode 11 is reduced to about half the setting value due to dishing, there exists no case in the plurality of the lower electrodes 11 in which the thickness thereof is reduced to half.

According to the semiconductor device of the first embodiment of the present invention described above, by raising the resistance against the excessive polishing of the lower electrode 11, the lower electrode 11 is prevented from being removed completely even if locally, so that occurrence of a capacitor undergoing pressure resistance failure can be prevented.

Although it is described above that the diameter of the contact plug 10a to be formed on the bottom portion of the electrode groove 11c is set larger than the diameter of the contact plug 10b to be formed in other area in the interlayer insulation film 6, the contact plug 10a is formed larger than any contact plug formed in the interlayer insulation film below the interlayer insulation film 6.

### Second Embodiment

Although the semiconductor device of the first embodiment of the present invention has indicated a structure in which the resistance against the excessive polishing of the lower electrode 11 due to the CMP is raised by increasing the DOF margin by setting the diameter of the contact plug 10a which connects the lower electrode 11 with the lower layer wiring electrically larger than the contact plugs of other portions, it is permissible to prevent occurrence of capacitor which induces pressure resistance failure by reducing the excessive polishing of the lower electrode.

That is, it has been found from the experiment of the inventor et al. that not only the excessive polishing of the lower electrode by the CMP is induced by deformation of a polishing pad for use in the CMP but also the degree of the excessive polishing differs depending on the quantity of contact plugs for connecting electrically the lower electrode with the lower layer wiring provided per unit area.

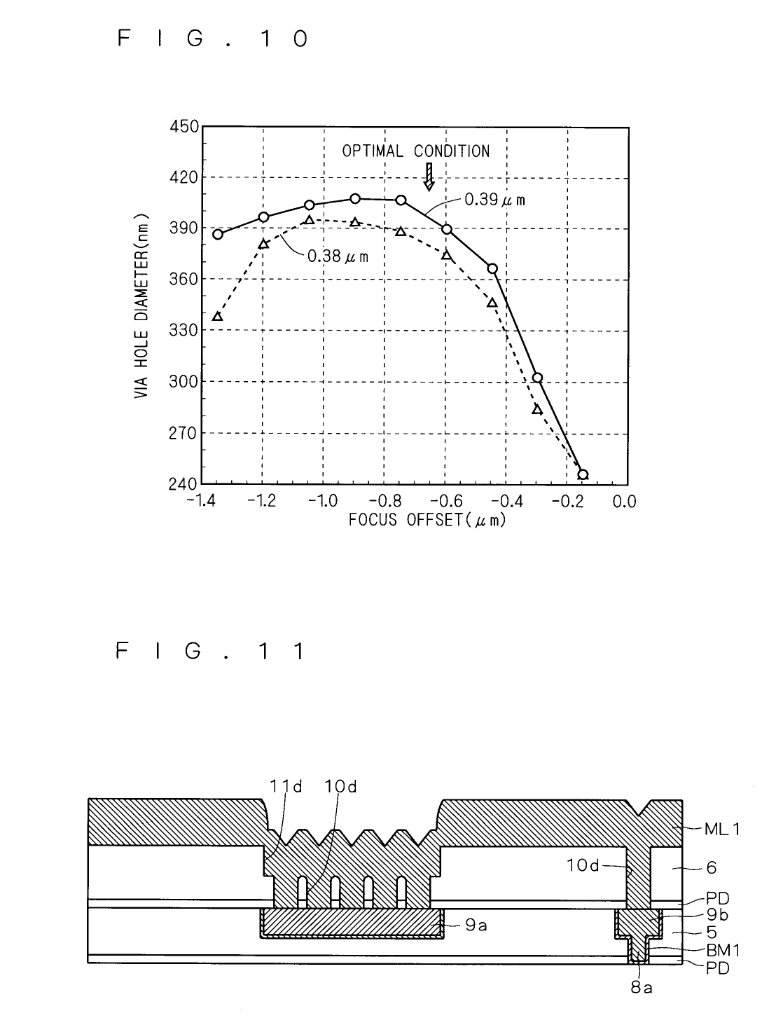

FIG. 11 is a sectional view showing a state in which tungsten film ML1 is formed on an entire surface of the interlayer insulation film 6 in formation process for the lower electrode 110 and the electrode groove 11d is filled with tungsten film ML1. The tungsten film ML1 is applied into the via holes 10d which are provided within the electrode groove 11d, reaching the wiring layer 9a on the bottom layer. Further, the via hole 10d which reaches the wiring layer 9b provided out of the capacitor formation area is filled with the tungsten film ML1.

The electrode groove 11d is shallower than the electrode groove 11c having a setting depth of 350 nm as shown in FIG. 4 and its setting depth is 250 nm. The diameter of the via hole 10d is unified to 0.36 μm. The representation of the barrier metal film is omitted for convenience.

Although five via holes 10d are provided within the electrode groove 11d in a section shown in FIG. 11, when the via holes 10d are provided, the thickness of the tungsten film ML1 at that portion is reduced to such an extent that the via hole 10d is buried. Then, if a plurality of the via holes 10d are gathered as shown in FIG. 11, the average film thickness of the tungsten film ML1 within the electrode groove 11d is reduced.

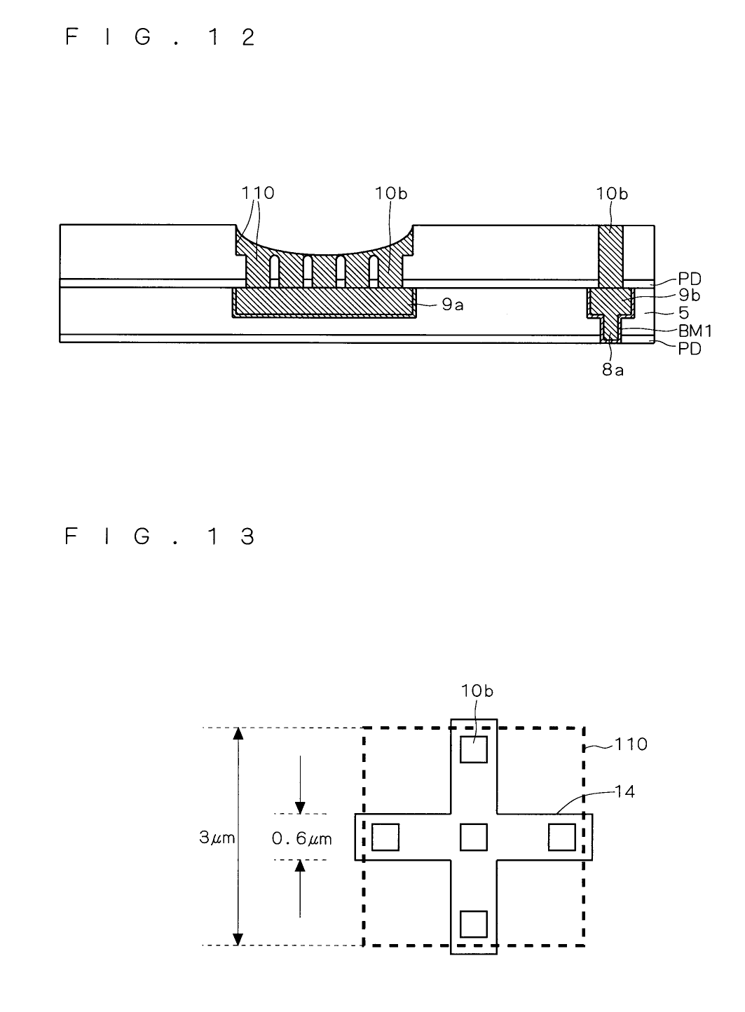

If the CMP is carried out with this condition, the dishing becomes remarkable within the electrode groove 11d whose average film thickness has been reduced. As a consequence, it has been found that the lower electrode 110 can be removed completely in a local area as shown in FIG. 12.

Then, it has been found that if the quantity of the via holes 10d within the electrode groove 11d is so set that the average film thickness of the tungsten film ML1 is not reduced largely, such a rate that the lower electrode 110 is removed completely in a local area can be reduced.

FIG. 13 shows an example of a pattern in which the contact plugs 10b (that is, via hole 10d) are provided, obtained based on the above finding.

FIG. 13 is a plan view of the capacitor as viewed from the topmost layer wiring side, in which the lower electrode 110 is indicated with a dotted line and five contact plugs 10b are provided in a cross shape along the central axis in the longitudinal and lateral directions on the lower electrode 110 which is a square in a plan view.

In the meantime, the topmost layer wiring 14 on the top of the lower electrode 110 is provided along the arrangement of the contact plug 10b and its width is about 0.6 μm.

The length of the lower electrode 110 in the longitudinal and lateral directions is 3 μm and if about three contact plugs 10b are provided in an area 3 μm long, the average film thickness of the tungsten film ML1 is never reduced, so that it can be said that the rate that the lower electrode 110 is removed completely in a local area can be reduced.

In the meantime, arrangement of the contact plugs 10b in a cross shape is just an example, but the contact plugs 10b may be provided in two rows in parallel within the lower electrode 110 or the contact plugs 10b may be provided in a single row.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising a capacitor including:
an interlayer insulation film provided above a semiconductor substrate;
a lower electrode provided in the top layer portion of said interlayer insulation film;
a dielectric film provided on said lower electrode; and
an upper electrode provided so as to be opposed to said lower electrode with said dielectric film interposed therebetween, wherein
said lower electrode is integrated with a contact plug provided so as to penetrate said interlayer insulation film from the bottom portion of said lower electrode in a direction perpendicular to a main surface of said semiconductor substrate, and
a diameter of said contact plug is set larger than a diameter of another contact plug provided so as to penetrate said interlayer insulation film in the direction perpendicular to the main surface of said semiconductor substrate.

2. The semiconductor device according to claim 1 wherein the diameter of said contact plug is 1.05 times or more the diameter of said another contact plug.
